(19) United States
(12) Patent Application Publication
(10) Pub. No.: US 2010/0053897 A1
(43) Pub. Date: Mar. 4, 2010

(54) ELECTRONIC EQUIPMENT

(75) Inventors: Hiroyuki Kusaka, Mitaka-shi (JP); Hirofumi Morita, Fussa-shi (JP)

Correspondence Address: BLAKELY SOKOLOFF TAYLOR & ZAFMAN LLP, 1279 OAKMEAD PARKWAY, SUNNYVALE, CA, 94085-4040, US

(73) Assignee: KABUSHIKI KAISHA TOSHIBA, Tokyo (JP)

(21) Appl. No.: 12/431,681

(22) Filed: Apr. 28, 2009

(30) Foreign Application Priority Data
Aug. 27, 2008 (JP) 2008-218566

(51) Int. Cl. H05K 7/20

(52) U.S. Cl. 361/697; 361/707

(57) ABSTRACT

Electronic equipment has a first circuit substrate disposed in opposition with the second circuit substrate, a first heat generating component mounted on the first circuit substrate, a first heat receiving portion thermally connected the first heat generating component, a second heat generating component mounted on a surface of the second circuit substrate, a second heat receiving portion thermally connected the second heat generating component, and a holding member having a first and a second elastic holding portion for pressing the first and second heat receiving portion in the direction of the first and second heat generating component and a supporting portion for supporting the first elastic holding portion and the second elastic holding portion and a plurality of fixing portion for fixing the supporting portion between the first circuit substrate and the second circuit substrate.

### BACKGROUND OF THE INVENTION

1. Field of the Invention

The present invention relates to electronic equipment having a structure for cooling respective heat generating bodies mounted on circuit substrates disposed in opposition with each other.

2. Description of the Related Art

Heat generating bodies (electronic parts) such as a CPU, a north bridge, a graphic chip, and the like are mounted on circuit substrates arranged in a housing of electronic equipment. A plurality of the circuit substrates on which these heat generating bodies are mounted may be disposed such that they oppose with each other in the housing. In the electronic equipment, since it is required to reduce, in particular, the thickness of the housing, it is preferable to laminate the circuit substrates and cooling units of the heat generating bodies mounted on the circuit substrates in a small size in height.

Conventionally, Japanese Unexamined Patent Application Publication No. 2007-12930 discloses electronic equipment which makes it possible to cool a plurality of heat generating bodies with a good space efficiency.

In the electronic equipment disclosed in Japanese Unexamined Patent Application Publication No. 2007-12930, heat generating bodies are thermally connected to a heat receiving portion while maintaining the pressed state of the heat generating bodies against the heat receiving bodies using a spring as a press unit. However, when the respective heat generating bodies are disposed to the opposite surfaces of the single heat receiving portion with a predetermined offset width (be being offset from each other), a problem arises in that the pressed state of a heat receiving surface is made unstable. Further, since electronic parts as the heat generating bodies ordinarily have an allowable load set thereto, it is necessary to adjust the pressed states of the respective electronic parts.

### SUMMARY OF THE INVENTION

The present invention has been accomplished in view of such situation, and on objection of the present invention is to provide electronic equipment which can maintain a stable pressed state to thermal contact between heat generating bodies and heat receiving bodies mounted on circuit substrate disposed in opposition with each other in housing.

To solve the problems described above, electronic equipment according to the present invention has a first circuit substrate; a second circuit substrate disposed in opposition with the first circuit substrate; a first heat generating component mounted on the first circuit substrate; a first heat receiving portion thermally connected the first heat generating component; a second heat generating component mounted on a surface of the second circuit substrate opposing with the first circuit substrate; a second heat receiving portion thermally connected the second heat generating component; and a holding member having a first elastic holding portion for pressing the first heat receiving portion in the direction of the first heat generating component and a second elastic holding portion different from the first elastic holding portion for pressing the second heat receiving portion in the direction of the second heat generating component and a supporting portion for supporting the first elastic holding portion and the second elastic holding portion and a plurality of fixing portion for fixing the supporting portion between the first circuit substrate and the second circuit substrate.

In the electronic equipment according to the present invention, a stable pressed state can be maintained to thermal contact between the heat generating bodies and the heat receiving bodies mounted on the circuit substrates disposed in opposition with each other in the housing.

### BRIEF DESCRIPTION OF THE DRAWINGS

FIG. 1 is a perspective view of an outside appearance of a note type personal computer as an example of electronic equipment according to the present invention;

FIG. 2 is a view showing an outside appearance of a mounting structure of the personal computer in the embodiment;

FIG. 3 is a sectional view between III-III of the mounting structure of FIG. 2;

FIG. 4 is an exploded perspective view of a part of the mounting structure in the embodiment;

FIG. 5 is a plan view showing arrangements of a cooling unit and a holding member in the embodiment;

FIG. 6 is a sectional view showing a modification of the mounting structure in the embodiment;

FIG. 7 is a sectional view showing another modification of the mounting structure in the embodiment; and

FIG. 8 is a plan view showing arrangements of a cooling unit and a holding member in another modification in the embodiment.

### DESCRIPTION OF THE PREFERRED EMBODIMENTS

An electronic equipment according to an embodiment of the present invention will be described hereunder with reference to the accompanying drawings.

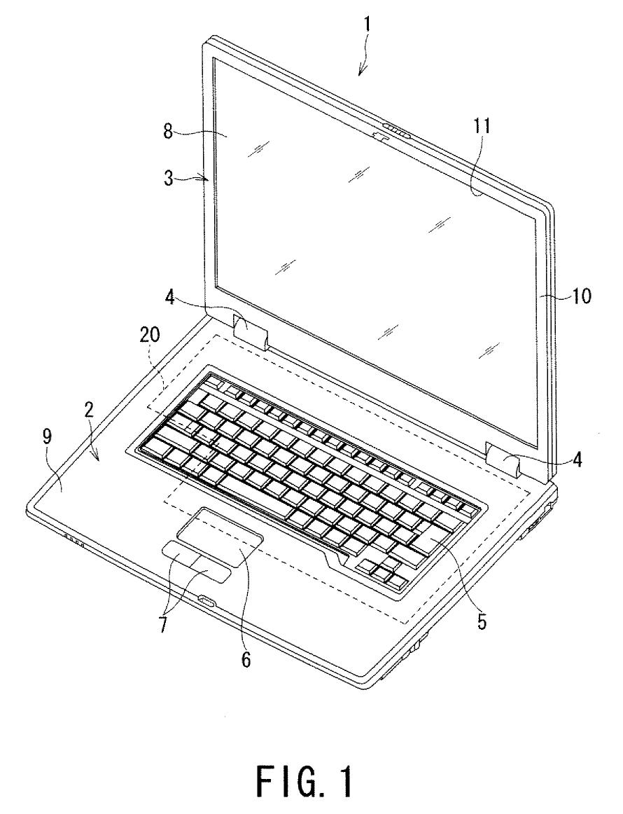

FIG. 1 is a perspective view of an outside appearance of a note type personal computer as an example of electronic equipment according to the present invention. In the personal computer 1, a display unit 3 is openably and closably connected to a main body 2 through a hinge unit 4. A keyboard 5 and a touch pad 6 as a pointing device, and buttons 7 are disposed on an upper surface of the main body 2. The display unit 3 has a display screen 8 composed of, for example, an LCD and the like in the inside thereof.

The main body 2 has a main body housing 9 made of resin and magnesium. The display unit 3 has a display unit housing 10 made of resin and magnesium likewise the main body 2. The display unit housing 10 has an exposure opening 11 for exposing the display screen 8 built therein.

The main housing 9 of the personal computer 1 has a mounting structure 20 accommodated therein.

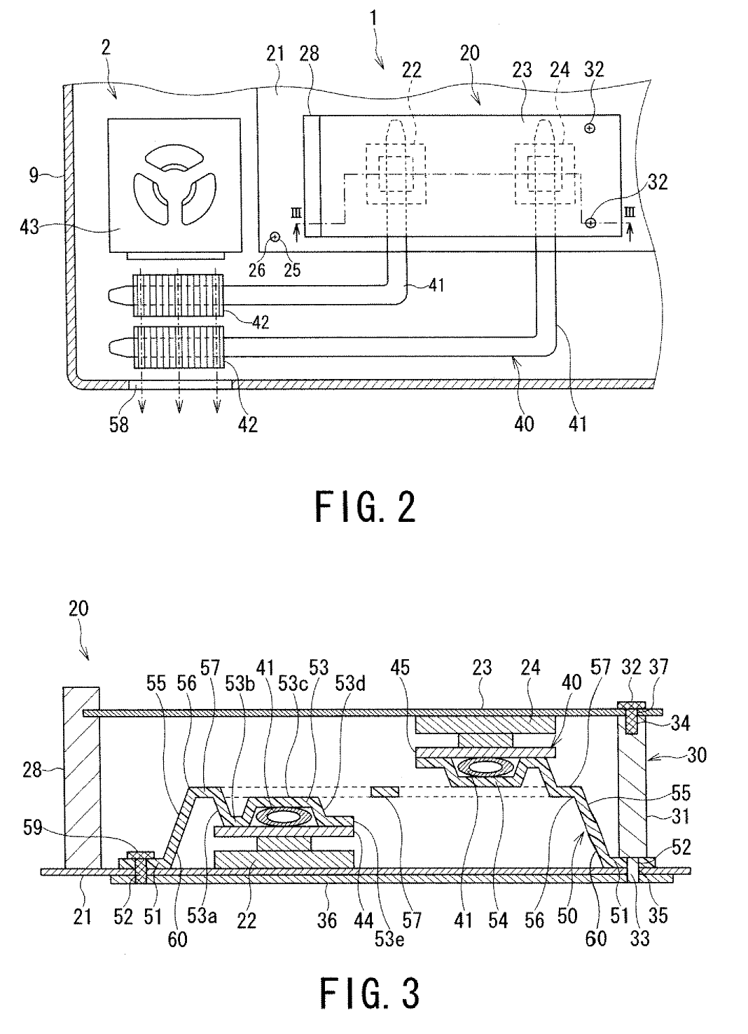

FIG. 2 is a view showing an outside appearance of the mounting structure 20 of the personal computer 1 in the embodiment. FIG. 3 is a sectional view between III-III of the mounting structure 20 of FIG. 2.

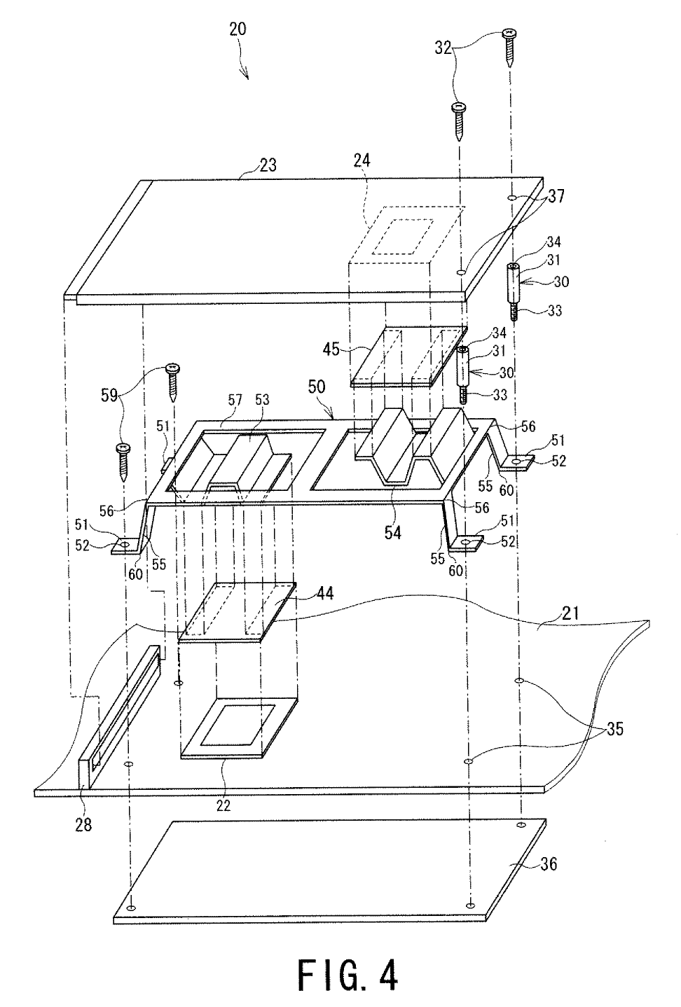

FIG. 4 is an exploded perspective view of a part of the mounting structure 20 in the embodiment. In the mounting structure of FIG. 4, heat pipes 41, radiation fins 42, and a fan 43 included in a cooling unit 40 are not shown.

The mounting structure 20 has a first circuit substrate (main substrate) 21, a first heat generating component 22, a second circuit substrate (sub substrate) 23, a second heat generating component 24, the cooling unit 40, and a holding member 50.

The main substrate 21 is a printed wiring board formed by laminating wiring layers made of copper. The main substrate 21 has a predetermined number of hole portions 25 formed thereto and fixed to the main housing 9 through screws 26 and the like. The first heat generating component 22 is mounted on the main substrate 21 at a predetermined position. The first heat generating component 22 is, for example, a BGA (Ball Grid Array) type semiconductor package and composed of electronic parts, for example, a CPU, a north bridge, a south bridge, and the like. The main substrate 21 has a connector 28 disposed at a predetermined position so that the main substrate 21 is electrically connected to the sub substrate 23 therethrough.

The sub substrate 23 is a printed writing board formed by laminating wiring layers made of copper likewise the main substrate 21. The second heat generating component 24 is mounted on a front surface of the sub substrate 23. The second heat generating component 24 is, for example, a BGA type semiconductor package and composed of, for example, a graphic chip.

The main substrate 21 is connected to the sub substrate 23 in such a manner that the surface of the main substrate 21, on which the first heat generating component 22 is disposed, opposes with the surface of the sub substrate 23, on which the second heat generating component 24 is disposed as well as the front surface of the main substrate 21 is disposed approximately in parallel with the front surface of the sub substrate 23. Further, in the embodiment, although the first and second heat generating bodies 22, 24 are disposed on the opposing surfaces, respectively, they are disposed with an offset width without being overlapped in the thickness direction of the main housing 9, i.e. they are disposed by being so-called offset with respect to the holding member 50.

As shown in FIG. 3, one end of the sub substrate 23, i.e. an illustrated left end thereof is electrically connected to the main substrate 21 through the connector 28 disposed to the main substrate 21. The main substrate 21 is connected to the sub substrate 23 by, for example, a stacking connector, a flexible print substrate (FPC), and a cable. Further, the other end of the sub substrate 23, i.e. an illustrated right end thereof is fixed to the main substrate 21 by studs 30 disposed at two positions of the right end corners of the sub substrate 23. Each of the studs 30 is composed of a stud main body 31 interposed between the main substrate 21 and the sub substrate 23 and a screw 32 which passes through the sub substrate 23 and is tightened to the stud main body 31. The stud main body 31 has a male screw portion 33 and a female screw portion 34. The male screw portion 33 passes through hole portions 35, 52 formed to the main substrate 21 and the holding member 50 to be described later and is screwed to a back plate 36. The screw 32 passing through a hole portion 37 formed to the sub substrate 23 is tightened into the screw portion 34.

Note that the back plate 36 has a function as a reinforcing member for preventing flexure generated to the main substrate 21 by the pressure received from the cooling unit 40.

The mounting structure 20 has the cooling unit 40 disposed thereto for cooling the first and second heat generating bodies 22, 24. The cooling unit 40 has a first heat receiving plate 44, a second heat receiving plate 45, and the two heat pipes 41 as well as the radiation fins 42 and the fan 43 shown in FIG. 2.

The first and second heat receiving plates 44, 45 as a first and second heat receiving portion are made of, for example, aluminum and formed in a rectangular thin plate shape which is approximately the same as that of the first and second heat generating bodies 22, 24. The first and second heat receiving plates 44, 45 is not limited to an aluminum material and may be formed of any material as long as it is good heat conduction material. The first and second heat receiving plates 44, 45 and the heat pipes 41 are fixed by welding and the like and thermally connected to each other. The heat pipes 41 are formed of, for example, a copper material, have one ends inserted into a space formed by the main substrate 21 and the sub substrate 23 and the other ends extending to the radiation fins 42. The radiation fins 42 are thermally connected to the heat pipes 41. The fan 43 cools the radiation fins 42.

As shown in FIG. 3, the first heat receiving plate 44 is thermally connected to the first heat generating component 22 through an illustrated lower surface thereof which opposes with a surface thereof on which a heat pipe 41 is fixed. The first heat receiving plate 44 is securely in contact with the first heat generating component 22 by coming into contact with the first heat generating component 22 through a heat conduction sheet, heat conduction grease, and the like (not shown) as a heat conduction member so that it efficiently executes heat conduction. The heat conduction sheet is composed of a material which is formed of, for example, a silicon rubber sheet and has a heat conduction property and an insulation property. The heat conduction grease is composed of, for example, a silicon-oil-based oil compound. The heat conduction grease is coated on a surface of the first heat generating component 22.

The personal computer 1 in the embodiment is provided with the holding member 50 so that a state that a predetermined stable load is applied between the first heat receiving plate 44 and the first heat generating component 22 and between the second heat receiving plate 45 and the second heat generating component 24 is maintained. The holding member 50 is formed of a material, for example, stainless steel which has a heat diffusion property and a predetermined strength as well as can apply elastic force to a target in contact therewith.

The holding member 50 has fixing portions 51 for fixing it to the main substrate 21 and first and second holding portions 53, 54 for applying elastic force.

The fixing portions 51 of the holding member 50 are formed of rectangular regions which they come into contact with the main substrate 21 approximately in parallel therewith. Each of the fixing portions 51 has the one hole portion 52. Two fixing portions 51 located on an illustrated right side shown in FIG. 4 are fixed to the main substrate 21 by the studs 30. That is, these fixing portions 51 are fixed to the main substrate 21 in such a manner that the male screw portions 33 of the stud main bodies 31 pass through the fixing portions 51, the main substrate 21, and the back plate 36 in this order so that they are tightened together by the male screw portions 33.

The other two fixing portions 51 located in the vicinity of the connector 28 of the main substrate 21 are tightened by screws 59 in the order of the fixing portions 51, the main substrate 21, and the back plate 36 so that they are fixed to the main substrate 21.

As shown in FIG. 4, standing portions 55, which stand up at a predetermined angle, are formed to the holding member 50 from side ends 60 thereof located inward of the fixing portions 51. Further, a rectangular frame portion 57 is formed to upper end portions 56 of the standing portions 55 so that these the upper end portions 56 are located at approximately the four corners of the frame portion 57, respectively, and further the first and second holding portions 53, 54 are formed to the frame portion 57. The first and second holding portions 53, 54 are formed by cutting out a part of a rectangular flat sheet which is disposed in parallel with front surfaces of the main substrate 21 and the sub substrate 23, for example. The frame portion 57 is formed of the remaining portion of the flat sheet from which the first and second holding portions 53, 54 are cut out.

The first holding portion 53 has elasticity and is formed as a leaf spring for pressing the first heat receiving plate 44 in the direction of the first heat generating component 22. The first holding portion 53 is formed so that it comes into surface contact with the upper surface shown in FIG. 3 of the first heat receiving plate 44 avoiding a region in which the heat pipe 41 is fixed. Specifically, as shown in FIG. 3, an inclining surface 53a is formed to the first holding portion 53 extending from the frame portion 57 and then a parallel surface 53b is formed thereto. The inclining surface 53a moves downward at a predetermined angle to the first heat receiving plate 44 located below the frame portion 57, and the parallel surface 53b comes into surface contact with the first heat receiving plate 44. Further, to avoid the heat pipe 41 fixed to the first heat receiving plate 44, the first holding portion 53 stands up at a predetermined angle and forms a non-contact portion 53c. Further, an inclining surface 53d is formed to the first holding portion 53 and then a parallel surface 53e is formed thereto. The inclining surface 53d moves downward at a predetermined angle and the parallel surface 53e comes into surface contact with the first heat receiving plate 44 again so that the first holding portion 53 comes into surface contact with the heat receiving plate 44 again. Since the first holding portion 53 has the shape described above, it comes into contact with the front surface of the first heat receiving plate 44 except the region thereof in which the heat pipe 41 is disposed region and presses the front surface.

The first holding portion 53 is formed taking it into consideration that the first heat receiving plates 44 is caused to come into contact with the first heat generating component 22 by an appropriate load. Specifically, the shape, the rigidity, and the like of the first holding portion 53 are determined so that a preferable load is applied to the first heat generating component 22 in consideration of the allowable load of the first heat generating component 22 and leakage and the like of the heat conduction grease to a periphery which caused when a heavy load is applied to the heat conduction grease coated between the first heat generating component 22 and the first heat receiving plate 44.

Note that the shape of the first holding portion 53 is not limited to the shape described above as long as it can apply a predetermined load to the first heat receiving plate 44.

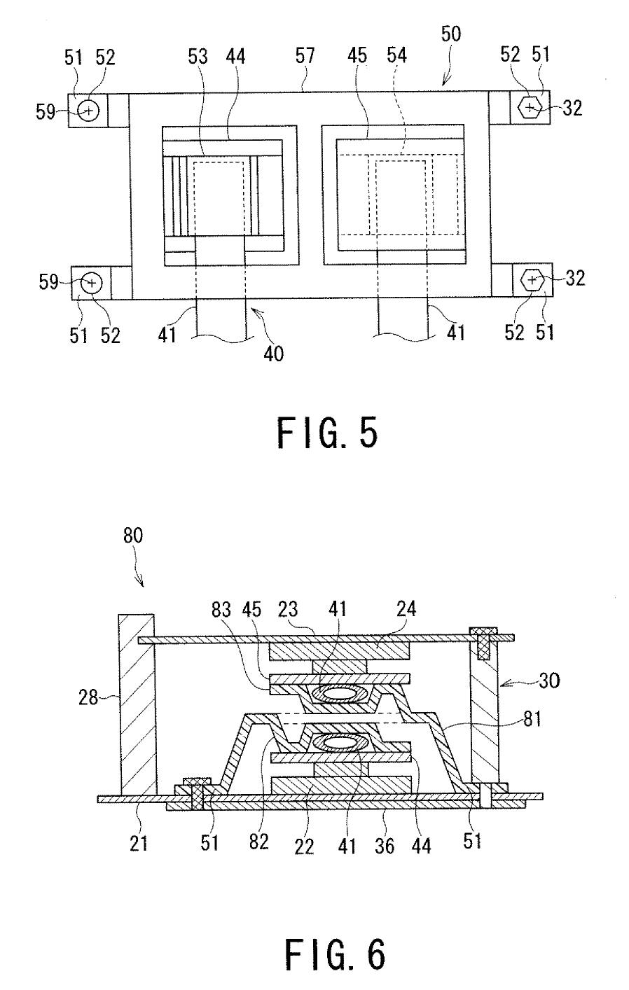

FIG. 5 is a plan view showing arrangements of the cooling unit 40 and the holding member 50 in the embodiment. As shown in FIG. 5, the first holding portion 53 is fixed by, for example, welding in a state that it is in contact with the first heat receiving plate 44 to which the heat pipe 41 is fixed, and the holding member 50 is arranged integrally with the cooling unit 40.

The second holding portion 54 has elasticity and is formed as a leaf spring for pressing the second heat receiving plate 45 in the direction of the second heat generating component 24. As shown in FIG. 3, the second holding portion 54 is formed symmetrical to the first holding portion 53 with respect to the center axes in a horizontal direction and a vertical direction of the frame portion 57. Note that since a specific arrangement of the second holding portion 54 is approximately the same as that of the first holding portion 53, the detailed explanation thereof is omitted.

A cooling action executed by the cooling unit 40 of the personal computer 1 of the embodiment will be explained. Note that since a cooling action to the first heat generating component 22 is approximately the same as that to the second heat generating component 24, only the cooling action to the first heat generating component 22 will be explained.

The heat generated by the first heat generating component 22 moves to the first heat receiving plate 44 through a not shown heat conduction member. At the time, the first heat receiving plate 44 is caused to come into surface contact with the first heat generating component 22 with a predetermined load by the elastic force of the first holding portion 53 of the holding member 50. Since the first holding portion 53 is previously formed such that an elastic force applied to the first heat receiving plate 44 is set to the predetermined load, heat is preferably transmitted between the first heat generating component 22 and the first heat receiving plate 44. The heat moved to the first heat receiving plate 44 is transmitted to the radiation fins 42 through the heat pipe 41. The radiation fins 42 are cooled by the fan 43, and heat is dissipated to the outside through a cutout portion 58 disposed to the main housing 9.

According to the personal computer 1, provision of the one holding member 50 can maintain thermal contact between the first heat generating component 22 and the first heat receiving plate 44 disposed to the main substrate 21 and thermal contact between the second heat generating component 24 and the second heat receiving plate 45 disposed to the sub substrate 23 in a stable pressed state without individually providing press units therewith. With this arrangement, a good cooled state can be maintained without deteriorating a space efficiency.

Further, since desired loads can be respectively determined to the first and second holding portions 53, 54 by providing the one holding member 50, preferable pressed states can be realized. For example, even if the allowable load of the first heat generating component 22 is different from that of the second heat generating component 24, a different pressed state can be realize by preferably determining the shapes, the rigidities, and the like of the first and second holding portions 53, 54 disposed to the one holding member 50.

Further, when the holding member 50 is fixed to the main substrate 21, an unnecessary increase of the number of screws and hole portions can be avoided by tightening the holding member 50 to the studs 30, which are used when the sub substrate 23 is fixed to the main substrate 21, together. This arrangement is effective in that the density of the circuit substrate can be increased and that the degree of freedom of a layout of the circuit substrate is not lost.

Note that although the example, in which the heat generating bodies such as the CPU and the like transmit heat to the heat receiving plates, to which the heat pipes are fixed, through the heat conduction sheet and the heat conduction grease as the heat conduction member, is applied to the embodiment, the embodiment is not limited thereto, and the arrangement of the cooling unit such as whether or not the heat receiving plates and the heat pipes are employed and the like may be determined according to the magnitude of power consumption (heat value) of the heat generating bodies.

Further, the back plate 36 as the reinforcing member may be replaced with other member (not shown) which has a predetermined strength and is disposed in the main housing 9 so as to act as the reinforcing member.

Although all the fixing portions 51 of the holding member 50 are fixed to the main substrate 21 by the studs 30 and the screws 32, they may be fixed to the sub substrate 23 when a stable pressed state can be maintained.

The mounting structure of the personal computer 1 in the embodiment can be applied to a layout of various parts by preferably forming the respective holding portions of the holding member according to a relative disposing relation between heat generating bodies. Modifications of the electronic equipment in the embodiment will be explained below.

FIG. 6 is a sectional view showing a modification of the mounting structure in the embodiment.

A mounting structure 80 shown in FIG. 6 is different from the mounting structure 20 shown in FIG. 3 in that a first heat generating component 22 is disposed approximately in opposition with a second heat generating component 24 through a holding member 81. Note that arrangements and portions corresponding to those of the mounting structure 20 are denoted by the same reference numerals, and overlapping explanation is omitted.

As shown in FIG. 6, even if the first heat generating component 22 is disposed approximately in opposition with the second heat generating component 24, a preferable pressed state can be realized by that a first holding portion 82 and a second holding portion 83 of the holding member 81 are formed in shapes by which preferable loads can be applied to a first heat receiving plate 44 and a second heat receiving plate 45.

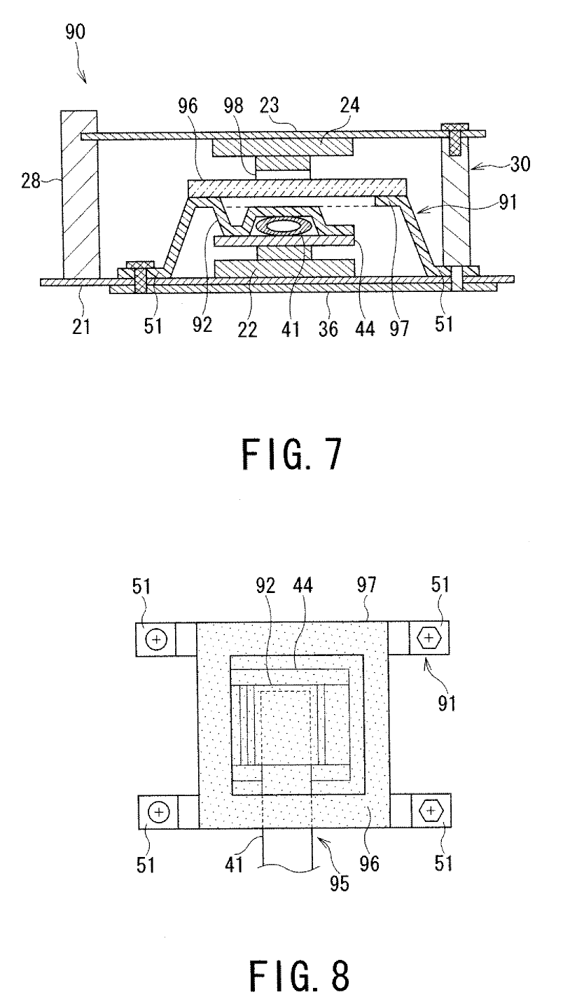

FIG. 7 is a sectional view showing another modification of the mounting structure in the embodiment. A mounting structure 90 shown in FIG. 7 is different from the mounting structure 80 shown in FIG. 6 in that a holding member 91 constitutes only a first holding portion 92 as a leaf spring.

When a first heat generating component is disposed approximately in opposition with a second heat generating component through a holding member, a holding portion that can be pressed may be disposed to any one of a first heat receiving plate and a second heat receiving plate. As shown in, for example, FIG. 7, the first holding portion 92 is disposed to the holding member 91 to apply a predetermined load to a first heat receiving plate 44 so that the pressed state between a first heat generating component 22 and a first heat receiving plate 44 is preferably held.

FIG. 8 is a plan view showing arrangements of a cooling unit 95 and the holding member 91 of the mounting structure shown in FIG. 7. Note that a region shown by hatching in FIG. 8 shows a second heat receiving plate 96. The second heat receiving plate 96 is disposed to have approximately the same shape as the outside shape of a frame portion 97 of the holding member 91 and bonded to and supported by the frame portion 97. Further, the second heat generating component 24 and the second heat receiving plate 96 are maintained in a pressed state through a heat conduction sheet 98 (FIG. 7) as a heat conduction member. At the time, a preferable pressed state is maintained between the second heat generating component 24 and the second heat receiving plate 96 making use of the elastic force of the heat conduction sheet 98. The holding member 91 formed as described above is effective in that the shape thereof can be simplified.

The electronic equipment according to the present invention can be applied not only to the note-book type personal computer explained above but also to other various types of electronic equipment such as a desk-top type computer, a word processor, acoustic equipment, communication equipment, and the like.

What is claimed is:

1. An electronic equipment comprising:
a first circuit substrate;
a second circuit substrate disposed in opposition with the first circuit substrate;
a first heat generating component mounted on the first circuit substrate;
a first heat receiving portion thermally connected the first heat generating component;
a second heat generating component mounted on a surface of the second circuit substrate opposing with the first circuit substrate;
a second heat receiving portion thermally connected the second heat generating component; and
a holding member having a first elastic holding portion for pressing the first heat receiving portion in the direction of the first heat generating component and a second elastic holding portion different from the first elastic holding portion for pressing the second heat receiving portion in the direction of the second heat generating component and a supporting portion for supporting the first elastic holding portion and the second elastic holding portion and a plurality of fixing portion for fixing the supporting portion between the first circuit substrate and the second circuit substrate.

2. The electronic equipment according to claim 1 wherein:
at least one of the shape or the rigidity of the first holding portion is determined so that a predetermined load is applied to the first heat receiving portion; and
at least one of the shape or the rigidity of the second holding portion is determined so that a predetermined load is applied to the second heat receiving portion.

3. The electronic equipment according to claim 2, further comprising:
a coupling member for coupling the first circuit substrate with the second circuit substrate at least one location,
wherein at least one of the fixing portion of the holding member is fixed to the first circuit substrate or the second circuit substrate by the coupling member.

4. The electronic equipment according to claim 4, wherein the first heat generating component and the second heat generating component are disposed through the holding member with an offset width without being overlapped.

5. The electronic equipment according to claim 4, wherein:
the first heat receiving portion and the second heat receiving portion are heat receiving plates; and
the electronic equipment further comprises heat pipes thermally connected to the heat receiving plates, radiation fins thermally connected to the heat pipes, and a fan for cooling the radiation fins.

6. The electronic equipment according to claim 5, wherein the first heat receiving portion and the second heat receiving portion are heat conduction sheets or heat conduction grease.

7. An electronic equipment comprising:
a first circuit substrate;
a second circuit substrate disposed in opposition with the first circuit substrate;
a first heat generating component mounted on the first circuit substrate;
a first heat receiving portion thermally connected the first heat generating component;
a second heat generating component mounted on a surface of the second circuit substrate opposing with the first circuit substrate;
a second heat receiving portion thermally connected the second heat generating component; and
a holding member having a elastic holding portion for pressing the first heat receiving portion in the direction of the first heat generating component and a supporting portion for supporting both the second heat receiving portion in the direction of the second heat generating component and the first elastic holding portion and a plurality of fixing portion for fixing the supporting portion between the first circuit substrate and the second circuit substrate.
